(19) United States
(12) Patent Application Publication
(10) Pub. No.: US 2025/0013666 A1
(43) Pub. Date: Jan. 9, 2025

(54) DYNAMIC STATISTICAL DATA ANALYSIS

(71) Applicant: INTERNATIONAL BUSINESS MACHINES CORPORATION, ARMONK, NY (US)

(72) Inventors: Pooja Bhargava, KIRKLAND, WA (US); Trinh Nguyen, San Jose, CA (US); Camvu Pham, San Jose, CA (US); Liese R. Yu, San Jose, CA (US); Terri A. Menendez, Santa Clara, MA (US)

(21) Appl. No.: 18/347,608

(22) Filed: Jul. 6, 2023

(51) Int. Cl. G06F 16/28; G06F 16/25

(52) U.S. Cl. CPC G06F 16/285; G06F 16/258

(57) ABSTRACT

A method, computer program product, and computer system are provided for analyzing statistical data. The statistical data is categorized into a plurality of datasets. A record field of a dataset of the plurality of datasets is selected. An artificial intelligence process is applied to the record field to generate an improvement value. A program corresponding to the record field is processed according to the improvement value.

### BACKGROUND

Embodiments of the present invention relate generally to tools for statistical data analysis, and more specifically, to the use of artificial intelligence and/or mathematical algorithms to analyze statistical data to detect potential computer program performance issues based on the statistical data.

### SUMMARY

Embodiments of the present invention provide a method, a computer program product, and a computer system, for analyzing statistical data. One or more processors of a computer system receive a plurality of statistical data. The one or more processors categorize the statistical data into a plurality of datasets. The one or more processors select a record field of a dataset of the plurality of datasets. The one or more processors apply an artificial intelligence process to the record field to generate an improvement value. The one or more processors process a program corresponding to the record field according to the improvement value.

### BRIEF DESCRIPTION OF THE DRAWINGS

FIG. 1 depicts a computing environment which contains an example of an environment for the execution of at least some of the computer code involved in performing the inventive methods, in accordance with embodiments of the present invention.

FIG. 2 is a schematic block diagram illustrating an environment for analyzing dynamic statistical data, in accordance with embodiments of the present invention.

FIG. 3 is a block diagram of a statistical data analysis system, in accordance with embodiments of the present invention.

FIG. 4 is a flow chart of an embodiment of a method for analyzing dynamic statistical data, in accordance with embodiments of the present invention.

FIG. 5 is an illustration of flow paths between elements of a computer system for analyzing dynamic statistical data, in accordance with embodiments of the present invention.

### DETAILED DESCRIPTION

### Overview

Statistical data is useful in computing environments for providing a snapshot of current activity. Statistical data is often collected by a computer for use where users rely on software tools to analyze the data for a specific purpose, and discards any unused, expired, or irrelevant statistical data. However, this data may nevertheless be of use when analyzed using artificial intelligence. For example, instead of discarding this data, the statistical data can be further analyzed and categorized into different datasets using artificial intelligence combining with experience-derived mathematical formula to establish new machine learning (ML) models to improve program behavior.

Modern computers receive and process input statistical data by applying a standardized method, such as an IBM System Management Facility (SMF), for generating records of activity from the input statistical data, which are recorded to a file to be analyzed for application performance and debug issues. Recorded activities may include I/O, network activity, software use, error conditions, and so on.

However, statistical data recorded in a raw format by the standardized method, e.g., to generate statistical data records in a SMF format, must be formatted or processed to be human readable. There are tools available that provide a user readable interface for rendering statistical data records to be human readable, but they only display data in a table format and still require human expertise to manually view and analyze the records to arrive at a recommendation to improve application performance for dataset usage, better cache, and buffer utilization. Especially in a coupling facility environment or mainframe computer processor this process requires a tedious effort to collect the statistical data records from several systems to compare and analyze them. The time-consuming process of analyzing statistical data records requires substantial training, tooling, and overall can be prone to error.

Embodiments of the present invention improve conventional statistical data record collection analysis techniques by providing a software tool that analyzes statistical data, in particular, dynamic statistical data, using machine learning (ML) models and experience-derived mathematical algorithms to automatically detect potential computer program performance issues based on the statistical data logged by a computer system. In some embodiments, the tool can include web server-client GUI software hosted on any machine locally or remotely to collect statistical data and communicating with special-purpose software modules on a host computer and an artificial intelligence system to analyze the statistical data recorded in a standardized format, which generates improvement values used to provide recommendations to assist a user with improving program performance.

For example, if a user wants to improve the performance of a dataset or system, they require a high level of expertise about the system. If a customer asks about improving the performance of a computer, the customer generally asks an expert to analyze the computer system setup and attributes. The expert uses her knowledge along with some mathematical formulas to assess the buffer sizes and other input file statistics, that their cache size needs to be adjusted. This knowledge is built from extensive years of experience and could be considered lost without her expertise and input. The present invention can retain all these formulas along with input data to build AI models which will, over time, be able to provide similar recommendations to users on how to improve their dataset/system performance.

### Computing Environment

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, a block 180 includes new code for analyzing dynamic statistical data. In addition to block 180, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 180, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

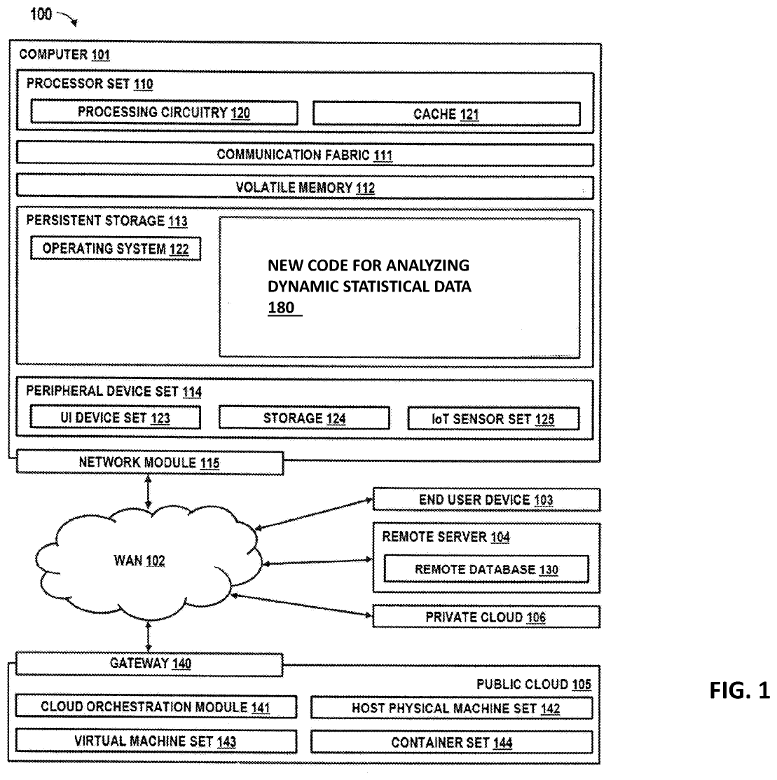

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 180 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 180 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Process and System for Analyzing Dynamic Statistical Data

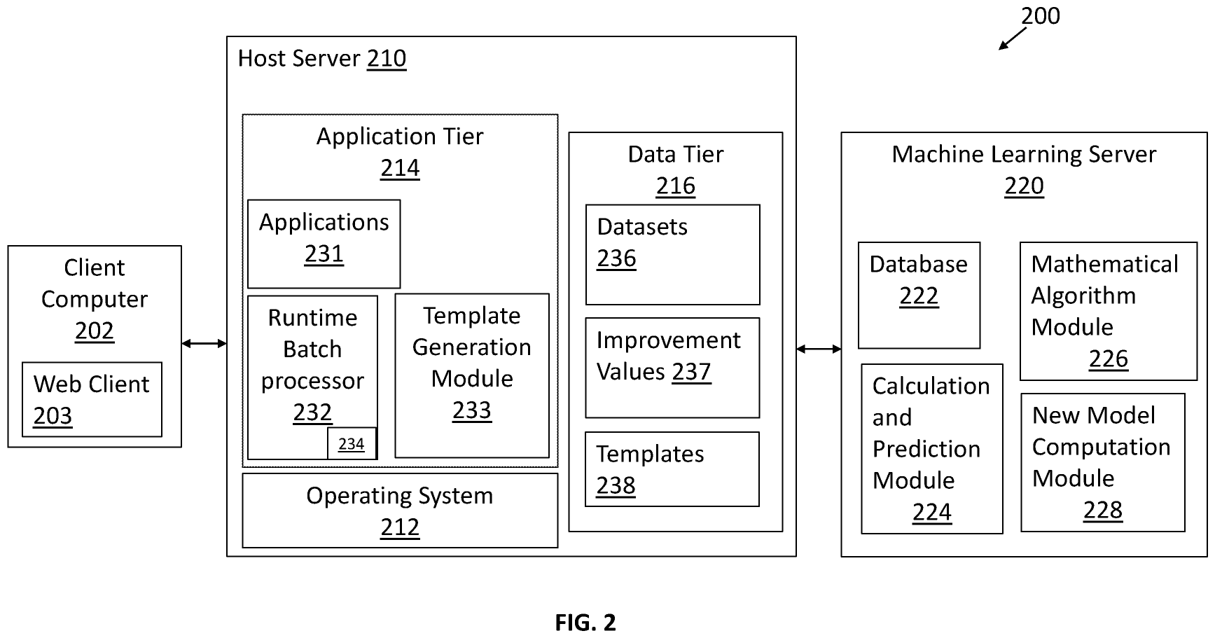

FIG. 2 is a schematic block diagram of an environment 200 for analyzing dynamic statistical data, in accordance with embodiments of the present invention.

The environment 200 includes a client computer 202, a host server 210, and a machine learning server 220. Although not shown in FIG. 2, the client computer 202, host server 210, and machine learning server 220 can each includes one or more processors, non-transitory computer readable medium or memory, input/output (I/O) interface devices, and/or peripheral devices, for example, described in other embodiments of a computing environment 100 of FIG. 1. At least some of the components shown and described in FIG. 2 may be software components stored and executed by the new code for analyzing dynamic statistical data at block 180 of FIG. 1.

The client computer 202 executes programs that transmit requests to the host computer 210 such as a mainframe computer for performing operations in accordance with the requests. The client computer 202 can include a web client 203 or other computer programs that access and view data from the host server 210. For example, the web client 203 can include a client application such as web browser. In some embodiments, the web client 203 is part of a web application for allowing access to inputs by the host server 210. In some embodiments, the web client 203 includes a Graphical User Interface (GUI) that connects a user to another computer to locally or remotely to collect inputs such as statistical data, from the other computer. For example, an input may include statistical data regarding the size of a control interval, referred to as a CI Size, which can be used for debugging purposes by a system programmer or application developer. In this example, the CI Size may affect record processing speed and storage requirements related to buffer space of I/O operations, and may require analysis and a computer-generated recommendation on modifying the CI Size to improve program behavior.

The host server 210 facilitates data exchanges with the machine learning server 220 and client computer 202. For example, the client computer 202 provides inputs to or display outputs from the host server 210 via a web browser of the web client 203. Embodiments of the architecture of the host computer 210 include an operating system 212, an application tier 214, and a data tier 216. In some embodiments, the host server 210 employs a mainframe architecture, for example, where the operating system 212 is a Z/OS® operating system offered by International Business Machines Corporation (IBM®), Armonk, N.Y.

The application tier 214 processes the statistical data collected from the client computer 202. In doing so, embodiments of the application tier 214 comprise one or more distributed middleware components such as servlets, dynamic link libraries (DLLs), scripts, and/or other similar components. Other embodiments of the application tier 214 include transaction management tools and/or message-based transaction manager tools. For example, IBM's Customer Information Control System (CICS) or IBM's Information Management System (IMS). The application tier 214 also facilitates access to a framework at the data tier 216 during the processing of the applications 231 such as an IBM Node.js® SDK (software developer kit) for building libraries or applications for a runtime batch processor 232 such as a Node.js® JavaScript runtime environment. The application tier 214 includes a template generation module 233 that groups or categorizes statistical data received from the client computer 202 into templates 238, which can be used to create job streams. A template allows a user to produce instructions specific to a job, which include a set of steps, each invoking a program. More specifically, a template provides a sample test case including steps generated to acquire the statistical data records, or statistical data collected for input to the machine learning server 220, for a dataset, or user input file to be analyzed by the machine learning server 220. Each set of input statistical data has a different template. The runtime batch processor 232 executes jobs from the templates as batches, commands, executables, e.g., according to an application development language such as Restructured Extended Executor (REXX). The resulting outputs are stored as datasets 236, which can be stored at the data tier 216. The runtime batch processor 232 includes independent systems that perform independent batch jobs or automated processes for each template.

The data tier 216 may be responsible for storing and retrieving information from various databases and/or file systems. The data tier 216 passes information requested by the application tier 214 for processing batch jobs or the like, for example, batch jobs controlled by job control language (JCL) statements that are required to run a particular program having a particular job step and specify the datasets that must be accessed, and may output the data to the client computer 202 for viewing by a user. The statements can be replaced with values, i.e., improvement values 237 described below, specific to the user environment.

As shown in FIG. 2, the data tier 216 may store inputs received from the client computer 202 such as statistic data. The data tier 216 can also store inputs received from the machine learning server 216 such as data constructed in JSON or the like within the operating system 212.

The machine learning server 220 includes a database 222, a calculation and prediction module 224, a mathematical algorithm module 226, and a new model computation module 228. In FIG. 2, the machine learning server 220 is separate from and in communication with the host server 210. In other embodiments, some or all of the database 222, a calculation and prediction module 224, a mathematical algorithm module 226, and a new model computation module 228 are stored and processed at the host server 210, for example, under the application tier 214. In some embodiments, an artificial intelligence (AI) engine is at the application tier 214 and a knowledge base is at the data tier 216. However, in FIG. 2, the database 222 can include a knowledge base, and an AI engine can include some or all of the calculation and prediction module 224, a mathematical algorithm module 226, and a new model computation module 228.

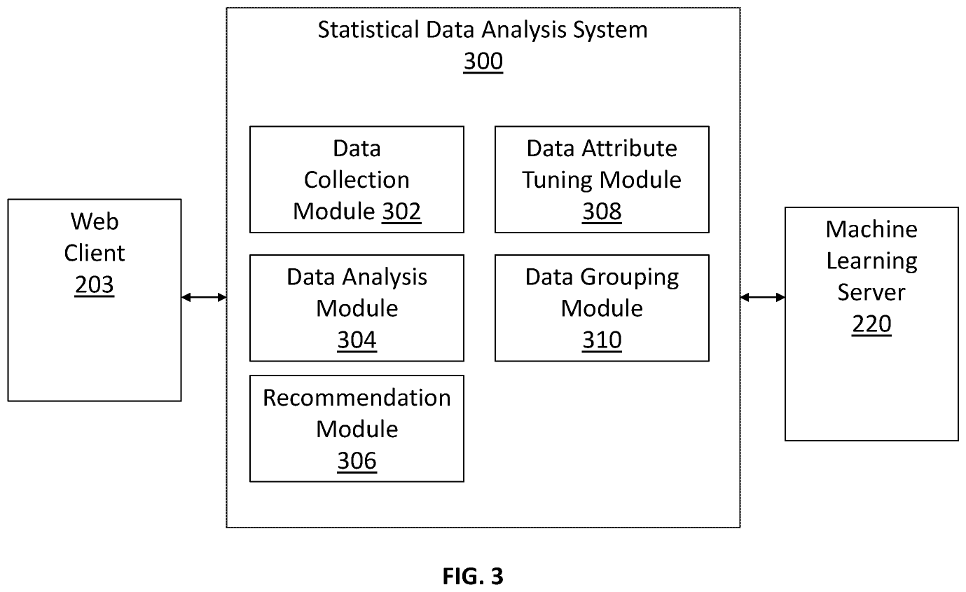

FIG. 3 is a block diagram of a statistical data analysis system 300, in accordance with embodiments of the present invention. The modules of the statistical data analysis system 300 can be stored and processed at block 180 of computing environment 100 shown in FIG. 1 and/or the host server 210 of FIG. 2.

As shown, the statistical data analysis system 300 includes a data collection module 302, a data analysis module 304, a recommendation module 306, a data attribute tuning module 308, and a data grouping module 310.

The data collection module 302 receives and processes statistical data received from a user such as a system programmer or application developer. The collected statistical data may be subsequently processed for extracting relevant information used by analysis by the machine learning server 220.

The data analysis module 304 communicates with the machine learning server 220 to analyze the statistical data at the data collection module 302 using artificial intelligence systems of the machine learning server 220 such as the calculation and prediction module 224, mathematical algorithm module 226, and/or new model computation module 228.

The recommendation module 306 generates possible notifications such as recommendations from the analyzed statistical data that may be used to improve the performance of program produced or otherwise used by a system programmer, application developer, or other user. In some instances, if there are abnormal settings regarding the dataset, the recommendation module 306 will alert to the programmer that such settings are not recommended.

The data attribute tuning module 308 permits users to tune datasets, or more specifically, an existing dataset's attributes, for example, to balance caches or lock structures. For example, a user can use the web client 203 to receive a recommendation from the recommendation module 306 about changing the size of caches, buffers or lock structures used by a VSAM RLS to make maximum use of caches and buffers without the need of reading and writing to a direct access storage device (DASD) for every single operation. The user can use the recommendation for a CI size that helps optimize access to storage usage, and use the data attribute tuning module 308 to tune this attribute.

The data grouping module 310 groups or categorizes the statistical data at the data collection module 303 into different sets of input statistical data with their respective output. The grouping of sets of input statistical data may include a template for each set so that the template can be independently processed by an independent operating system of the runtime batch processor 232. The runtime batch processor 232 may have a plurality of independent processing systems 234, e.g., z/OS® systems, that operate together as a cluster or other data sharing arrangement. For example, each independent processing system is one of a plurality of independent processing systems of a cluster or other data sharing arrangement that cooperate to process the statistical data arranged into templates.

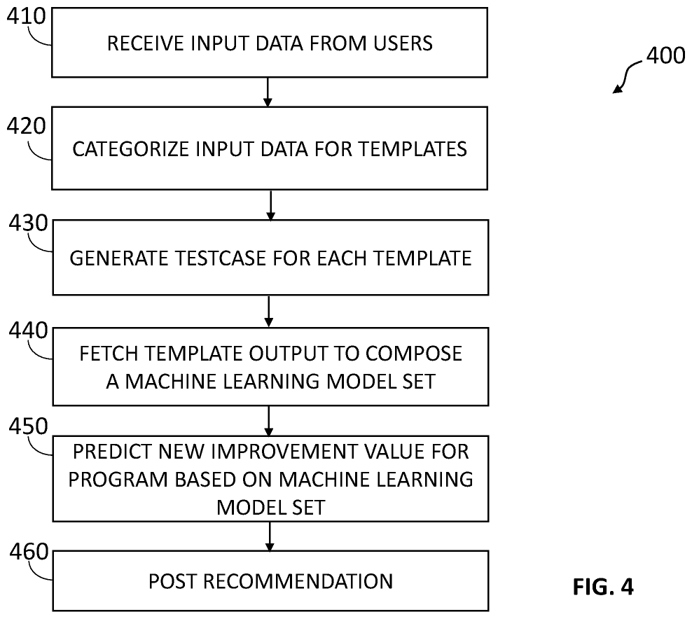

FIG. 4 is a flow chart of an embodiment of a method 400 for analyzing dynamic statistical data, in accordance with embodiments of the present invention. In describing the method 400, reference is made to elements of FIGS. 2 and 3. Accordingly, some or all of the method 400 is performed in the environment 200 of FIG. 2 and/or statistical data analysis system 300 of FIG. 3.

At step 410, the web client 203 of the client computer 202 receives input data from at least one user. The input data preferably includes dynamic statistical data pertaining to attributes that can be generated dynamically, or “on-the-fly”, and collected by the client computer 202 from other information sources via a network (not shown). The input data may include computer attributes for subsequent tuning or modification by the machine learning server 220.

At step 420, the statistical data of the inputs collected in step 410 is categorized for a plurality of different templates. A template is generated for providing instructions specific to a job regarding a specific input of statistical data, or more specifically, computer attributes of the statistical data. In particular, the template is generated after adding steps in a job to acquire statistical data records corresponding to the inputs. Each input of the input data has a different template. For example, a first input may include values of a CI Size and a second input may include values of a cache buffer. Other computer attributes may include but not be limited to SMF Subtype or lock structure. The statistical data analysis system 300 generates a first template for the first input and a second template for the second input.

At step 430, a testcase is generated for each template. A template testcase generates a program, which will run to collect the statistical data, or records for a dataset. For example, steps of a job are added to acquire the records, where a template testcase is modified with the added steps to make a program for collecting statistical data generic. In some embodiments, after a template is created, it is output to an independent processing system 234 of the runtime batch processor 232, to be executed as batches, commands, executable files, or other feature of the independent processing system 234. The resulting outputs are saved in one or more datasets.

At step 440, one of the template outputs including the statistical data is fetched for feeding to the machine learning server 220 to compose a machine learning model set. In an AI modeling process, there will be many datasets that will be fetched to the invention apparatus to compose a model set of data. Each dataset has many different record fields, and one of the record fields is selected to make improvements upon, for example, for predicting improvement values that can modify, and improve a computer attribute such as a control interval (CI) size, SMF Subtype, cache buffer, and/or lock structure. In some embodiments, the improvement value includes a predicted new value for a computer attribute control interval (CI) size, cache value, buffer pool, or lock structure for a record type of the inputs.

At step 450, a new improvement value is predicted for a program based on the model set of data, or more specifically, a selected record field of the collected dataset used to compose the model set of data, which can be used improve application program performance for dataset usage, cache enhancements, and buffer utilization, but not limited thereto. The machine learning server 220 can execute and artificial intelligence process can be carried out with machine learning modeling provided by the calculation and prediction module 224 and/or an experience-derived formula provided by the mathematical algorithm module 226 and defined by a user. All model datasets will be saved at the database 222.

At step 460, a recommendation generated according to the improvement value is posted to the client computer 202. The recommendation according to the improvement value may relate to the program corresponding to an input including the selected record field.

The method 400 can be applied in the following example. At step 410, a plurality of user inputs is received, including cache size, buffer size, and dataset define attributes. A user may desire to modify or otherwise improve a computer, for example, improve throughput, processing speed, debugging, and so on. A user request may include the user inputs so that the statistical data analysis system 300 in communication with a machine learning environment can detect potential computer program performance issues based on the statistical data. At step 420, the template generator processor 233 can add steps in a job, e.g., a JCL job so that at step 430, a template testcase can be filled in to allow the program for collecting the statistical data records to be generic, i.e., for collecting statistical data records for a dataset generated for the template provided as an input. Also, the different inputs (cache size, buffer size, dataset define attributes) are categorized to create the job. At step 440, after the template job is acquired, the template job is executed on an independent processing system 234 to fetch the statistical data records for output to the machine learning server 220. A mathematical formula may be used to determine if the cache is not big enough to support the buffer size since there is no current machine learning model data present. The data is saved in the machine learning server for future prediction purposes (step 450). At step 460, the machine learning output returns the new recommended cache size (i.e., new improvement value) to the user.

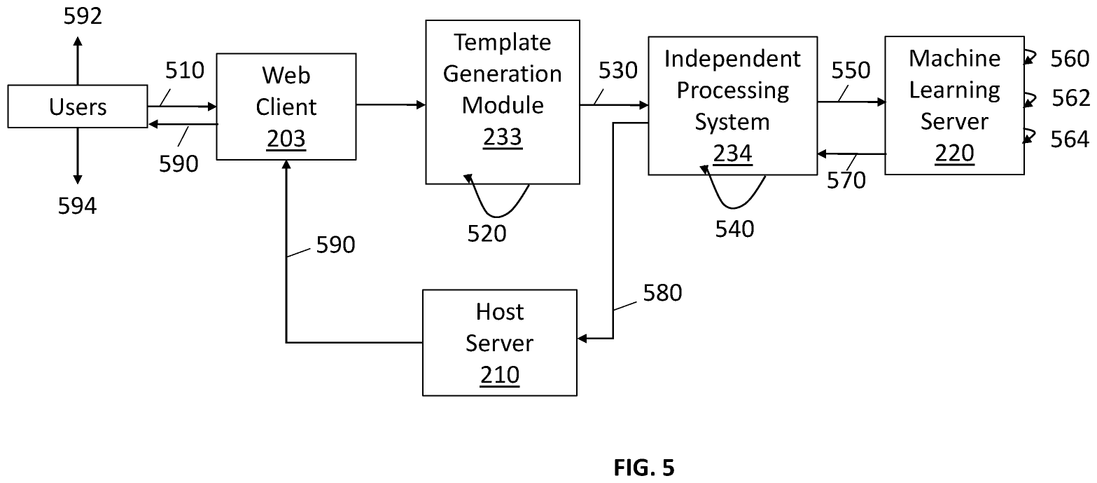

FIG. 5 is an illustration of a flow paths between elements of a computer system 500 for analyzing dynamic statistical data, in accordance with embodiments of the present invention. The computer system 500 may be similar to one or more computer systems and/or processors of the environment 200 of FIG. 2 and the statistical data analysis system 300 of FIG. 3. In the illustration shown in FIG. 5, the operating system is a z/OS® operating system, and the host server 210 of the computer system 500 executes processes statistical data in a Statistic Management Facility (SMF) raw format.

The web client 203 receives (510) one of more inputs from one or more users. An input preferably includes statistical data having at least one computer attribute such as control interval (CI). The inputs can include dynamic statistical data used by the statistical data analysis system 300 for tuning a dataset. In some embodiments, the inputs can include data for tuning buffers, caches, and/or lock structures. In some embodiments, one or more inputs are received from another system or subsystem, for example, a z/OS® system of an IBM sysplex environment. The web client 203 outputs the statistical data to the host server 220.

The template generation module 233 transforms (520) the input data into templates, for example, JCL templates. For example, a JCL template includes statements required to run a particular program corresponding to an attribute of statistical data of an input, for example, CI size. In this example, the template generated from the CI size input is submitted (530) to a corresponding independent processing system 234 of the runtime batch processor 232, for example, a z/OS® system. In some embodiments, the independent processing system 234 receives queries or test datasets for execution to determine the manner in which jobs are to be executed at the independent processing system 234. In some embodiments, a node accessor library is used to access and tune the datasets and submit the templates to their respective independent processing systems 234. In some embodiments, a node accessor is part of the data attribute tuning module 308 of FIG. 3 for tuning datasets, buffers, cache, or lock structures, but not limited thereto. At the selected independent processing system, the jobs are executed (540) as JCL batches, commands, or other file access commands, and the outputs are saved in datasets.

The machine learning server 220 fetches and reads (550) a dataset and processes it for analysis. In some embodiments, at flow path 560, based on the existing SMF statistics, the calculation and prediction module 224 generates a new set of improvement values for the input SMF record types, e.g., stored in statistical data records at the data tier 216. For example, an artificial intelligence process is applied to a record field that includes predicting a new set of values for an input record type using the statistical data. In some embodiments, a relevant improvement value 237 may be stored in the data tier 216. In other embodiments, at flow path 562, if the improvement values 237 are not stored and the machine learning model does not exist, the mathematical algorithm module 226 calculates a new set of improvement values. At flow path 564, the model produced according to the experience-derived formula provided by the mathematical algorithm module 226 is saved and compared against existing models to compute a newer model and archive the older models.

At flow paths 570 and 580, the improvement value predicted by the machine learning server 220 is used to post an optimal size of the attributes of the dataset of interest, such as CIs, CF Cache, buffer pool size, and/or lock structure to the web SMF smart client. At flow path 590, the outputs are processed, for example, displayed in a tabular format or chart for user viewing. In some embodiments, a recommendation can be provided (592) based on the improvement value, for example, a CI size recommendation for an SMF subtype. In other embodiments, recommendations can be provided (594) regarding CF cache structure sizes, buffer pool sizes, or lock structure sizes.

In some embodiments, the computer system 500 can be applied to a VSAM RLS application for dataset tuning efficiencies. As described above, the manner in which a JCL describes jobs running on the host computer 220 and determination of improvement values using predetermined JCL templates permits the operating system 212 to allocate time and space resources efficiently, which can require less latency. This will be achieved if the collection of SMF subtype data is enabled. It may also be useful for an application programmer to adjust the CI size for a dataset based on usage and reduce the number of CI splits and reclaims. Another benefit to system programmers is to use this computer system 500 to receive recommendations about changing the size of caches, buffers or lock structures used by VSAM RLS to make maximum use of caches and buffers without the need of reading and writing to a direct access storage device (DASD) for every single operation. Once an SMF subtype is collected, the application programmer can use the recommendation for a CI size that helps optimize access to storage usage.

In some embodiments, the computer system 500 can be applied to a backend server such as the machine learning server 220, which can employ accumulative ML models to analyze LISTSTAT and LISTCAT command outputs as well as various statistical data records, e.g., SMF records, to find the most efficient CI size based on the workload ran for the current interval. LISTSTAT is SHCDS command to display real time statistics for a data set and LISTCAT command lists entries from a catalog for a dataset. It will also utilize average response times for the dataset. If there are abnormal settings such as ascending keys then the dataset is being written to at the end, the web GUI will alert to the programmer that such settings are not recommended. The server also calculates the cache, buffer manager and lock structure statistics and provides system programmers the sizing recommendation for the caches and buffers based on previous ML learning models combining with the below formula that has been widely applied to help improve many performance issues over the decade. Additionally, buffering success is measured by BMF hit rate, average elapse and CPU time, and LRU mode. For caches, a formula establishing that the sum of all the RLS cache structures equal the sum of all the RLS buffer pools across a multi-computer environment such as an IBM sysplex environment can be automatically applied to the collected data and alert users.

In some embodiments, a backend server constantly monitors buffer pool data and gives warning if total amount of buffer pools exceeds amount of real storage. For the recommendation of lock structure sizing, the following experience-derived formula (Eq. 1) can be used.

$$Lock\_Structure \_Size = 10 M * number\_of \_Systems \_in \_sysplex * Lock\_entry \_Size Update percent \qquad Eq . 1$$

In some embodiments, the machine learning server 220 includes an application program interface (API) (not shown) for plug-ins to process JSON and other format it has collected from the statistical data analysis system 300.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for analyzing statistical data, comprising:
receiving, by one or more processors of a computer system, inputs including a plurality of statistical data;
categorizing by the one or more processors of a computer system, the statistical data into a plurality of datasets;
selecting, by one or more processors of a computer system, a record field of a dataset of the plurality of datasets;
applying, by the one or more processors of a computer system, an artificial intelligence process to the record field to generate an improvement value; and
processing, by the one or more processors of a computer system, a program corresponding to the record field according to the improvement value.

2. The computer-implemented method of claim 1, further comprising:
posting, by the one or more processors of a computer system, a recommendation according to the improvement value regarding the program corresponding to an input including the selected record field.

3. The computer-implemented method of claim 2, wherein the improvement value includes a predicted new value for changing a size of a computer attribute control interval, cache, buffer pool, or lock structure.

4. The computer-implemented method of claim 1, wherein categorizing the statistical data into the plurality of datasets comprises:
transforming, by the one or more processors of a computer system, the statistical data into a template providing instructions for executing a unique job;
outputting the template to an independent processing system;
executing the unique job according to the instructions of the template; and
storing an output of the executed unique job in a dataset of the plurality of datasets.

5. The computer-implemented method of claim 4, wherein the independent processing system is one of a plurality of independent processing systems of a cluster or other data sharing arrangement that cooperate to process the statistical data arranged into templates.

6. The computer-implemented method of claim 1, wherein the record field includes a computer attribute, and the artificial intelligence process generates the improvement value for the computer attribute.

7. The computer-implemented method of claim 1, wherein the improvement value is predicted for a computer program by a machine learning model using the record field of the dataset.

8. The computer-implemented method of claim 1, wherein applying, by the one or more processors of a computer system, the artificial intelligence process to the record field comprises predicting a new set of values for a record type of the inputs using existing statistical data.

9. The computer-implemented method of claim 1, wherein applying, by the one or more processors of a computer system, the artificial intelligence process to the record field comprises executing a mathematical algorithm of the artificial intelligence process to calculate a new set of values for a record type of the inputs.

10. The computer-implemented method of claim 9, further comprising:
computing, by the one or more processors of a computer system, a new machine model generated by the artificial intelligence process.

11. A computer program product, comprising one or more computer readable hardware storage devices having computer readable program code stored therein, said program code containing instructions executable by one or more processors of a computer system to implement a method for analyzing statistical data, said method comprising the steps of:
receiving, by one or more processors of a computer system, inputs including a plurality of statistical data;
categorizing by the one or more processors of a computer system, the statistical data into a plurality of datasets;
selecting, by one or more processors of a computer system, a record field of a dataset of the plurality of datasets;
applying, by the one or more processors of a computer system, an artificial intelligence process to the record field to generate an improvement value; and
processing, by the one or more processors of a computer system, a program corresponding to the record field according to the improvement value.

12. The computer program product of claim 11, wherein the method further comprises:
posting, by the one or more processors of a computer system, a recommendation according to the improvement value regarding the program corresponding to an input including the selected record field.

13. The computer program product of claim 11, wherein categorizing the statistical data into the plurality of datasets comprises:
transforming, by the one or more processors of a computer system, the statistical data into a template providing instructions for executing a unique job;
outputting the template to an independent processing system;
executing the unique job according to the instructions of the template; and
storing an output of the executed unique job in a dataset of the plurality of datasets.

14. The computer program product of claim 11, wherein applying, by the one or more processors of a computer system, the artificial intelligence process to the record field comprises predicting a new set of values for a record type of the inputs using existing statistical data.

15. The computer program product of claim 11, wherein applying, by the one or more processors of a computer system, the artificial intelligence process to the record field comprises executing a mathematical algorithm of the artificial intelligence process to calculate a new set of values for a record type of the inputs.

16. A computer system, comprising one or more processors, one or more memories, and one or more computer readable hardware storage devices, said one or more hardware storage devices containing program code executable by the one or more processors via the one or more memories to implement a method for analyzing statistical data, said method comprising the steps of:
receiving, by one or more processors of a computer system, inputs including a plurality of statistical data;
categorizing by the one or more processors of a computer system, the statistical data into a plurality of datasets;
selecting, by one or more processors of a computer system, a record field of a dataset of the plurality of datasets;
applying, by the one or more processors of a computer system, an artificial intelligence process to the record field to generate an improvement value; and
processing, by the one or more processors of a computer system, a program corresponding to the record field according to the improvement value.

17. The computer system of claim 16, wherein the method further comprises:
posting, by the one or more processors of a computer system, a recommendation according to the improvement value regarding the program corresponding to an input including the selected record field.

18. The computer system of claim 16, wherein categorizing the statistical data into the plurality of datasets comprises:
transforming, by the one or more processors of a computer system, the statistical data into a template providing instructions for executing a unique job;
outputting the template to an independent processing system;
executing the unique job according to the instructions of the template; and
storing an output of the executed unique job in a dataset of the plurality of datasets.

19. The computer system of claim 16, wherein applying, by the one or more processors of a computer system, the artificial intelligence process to the record field comprises predicting a new set of values for a record type of the inputs using existing statistical data.

20. The computer system of claim 16, wherein applying, by the one or more processors of a computer system, the artificial intelligence process to the record field comprises executing a mathematical algorithm of the artificial intelligence process to calculate a new set of values for a record type of the inputs.
